(19) United States
(12) Patent Application Publication
(10) Pub. No.: US 2026/0157203 A1
(43) Pub. Date: Jun. 4, 2026

(54) ELECTRONIC DEVICE AND METHOD FOR MANUFACTURING THE SAME

(71) Applicant: Innolux Corporation, Miaoli County (TW)

(72) Inventors: Ju-Li Wang, Miaoli County (TW); Po-Yun Hsu, Miaoli County (TW); Chin-Ming Huang, Miaoli County (TW); Ker-Yih Kao, Miaoli County (TW)

(73) Assignee: Innolux Corporation, Miaoli County (TW)

(21) Appl. No.: 19/387,605

(22) Filed: Nov. 12, 2025

Related U.S. Application Data
(60) Provisional application No. 63/727,208, filed on Dec. 3, 2024.

(30) Foreign Application Priority Data
Jun. 27, 2025 (CN) 202510882014.9

(51) Int. Cl. H10W 70/65; H10W 70/05; H10W 70/60; H10W 70/63; H10W 90/00

(52) U.S. Cl. CPC H10W 70/65; H10W 70/095; H10W 70/611; H10W 70/635; H10W 90/724

(57) ABSTRACT

The present disclosure provides an electronic device and a method for manufacturing the same. The electronic device includes a substrate including first and second surfaces opposite to each other in a first direction, a cavity, and a through-hole penetrating the first and second surfaces, a bonding element disposed in the cavity, a first electronic unit disposed in the cavity and bonded onto the substrate through the bonding element, a conductive element disposed in the through-hole and electrically connected to the first electronic unit, a circuit structure disposed on the first surface of the substrate and electrically connected to the first electronic unit and the conductive element, and a connection element disposed on the conductive element, wherein a reflow temperature of the bonding element is higher than a reflow temperature of the connection element.

### CROSS-REFERENCE TO RELATED APPLICATION

This application claims the priority benefit of U.S. provisional application serial no. 63/727,208, filed on December 3, 2024, and China application serial no. 202510882014.9, filed on June 27, 2025. The entirety of each of the above-mentioned patent applications is hereby incorporated by reference herein and made a part of this specification.

### BACKGROUND

### TECHNICAL FIELD

The present invention relates to an electronic device and a method for manufacturing the same, and particularly relates to an electronic device with good reliability and a method for manufacturing the same.

### DESCRIPTION OF RELATED ART

In current semiconductor packaging technology, mounting electronic units with different functions on the same substrate is one approach to improving the performance of electronic devices. However, as electronic devices continue to be developed toward lighter, thinner, shorter, and smaller dimensions and user demands for electronic device performance continue to increase, the density of the electronic units mounted on the substrate is increasing continuously. As such, the alignment margin of the electronic units becomes more stringent, and the aspect ratio of the through holes penetrating the substrate continue to increase, thereby making it difficult for the conductive elements formed in the through holes to meet current or future needs in terms of reliability.

### SUMMARY

According to an embodiment of the present disclosure, an electronic device includes a substrate, a bonding element, a first electronic unit, a conductive element, a circuit structure, and a connection element. The substrate includes a first surface and a second surface opposite to each other in a first direction, wherein the substrate includes a cavity extending from the first surface into the substrate and a through hole penetrating through the first surface and the second surface. The bonding element is disposed in the cavity. The first electronic unit is disposed in the cavity and bonded to the substrate through the bonding element. The conductive element is disposed in the through hole and electrically connected to the first electronic unit. The circuit structure is disposed on the first surface of the substrate and electrically connects to the first electronic unit and the conductive element. The connection element is disposed on the conductive element, wherein the reflow temperature of the bonding element is higher than the reflow temperature of the connection element.

According to an embodiment of the present disclosure, a method for manufacturing an electronic device includes the following steps. A substrate including a first surface and a second surface opposite to each other in a first direction is provided, wherein the substrate includes a cavity extending from the first surface into the substrate and a through hole penetrating through the first surface and the second surface. A bonding element is provided in the cavity. A first electronic unit is provided on the bonding element, such that the first electronic unit is bonded to the substrate through the bonding element. A conductive element is provided in the through hole. A connection element is provided on the conductive element, wherein the reflow temperature of the bonding element is higher than the reflow temperature of the connection element.

### BRIEF DESCRIPTION OF THE DRAWINGS

FIG. 1 is a schematic cross-sectional view of an electronic device according to a first embodiment of the present disclosure.

FIG. 2 is a cross-sectional schematic diagram of an electronic device according to a second embodiment of the present disclosure.

FIG. 3 is a schematic cross-sectional view of a method for manufacturing an electronic device according to an embodiment of the present disclosure.

FIG. 4 is a schematic cross-sectional view of a method manufacturing for an electronic device according to another embodiment of the present disclosure.

FIG. 5 is a schematic cross-sectional view of an electronic device according to a third embodiment of the present disclosure.

FIGS. 6 and 7 are schematic cross-sectional views of methods for manufacturing a first electronic unit according to different embodiments of the present disclosure.

FIG. 8 is a schematic top view of a first electronic unit of the present disclosure.

FIG. 9 is a schematic cross-sectional view of a first electronic unit of the present disclosure.

### DESCRIPTION OF THE EMBODIMENTS

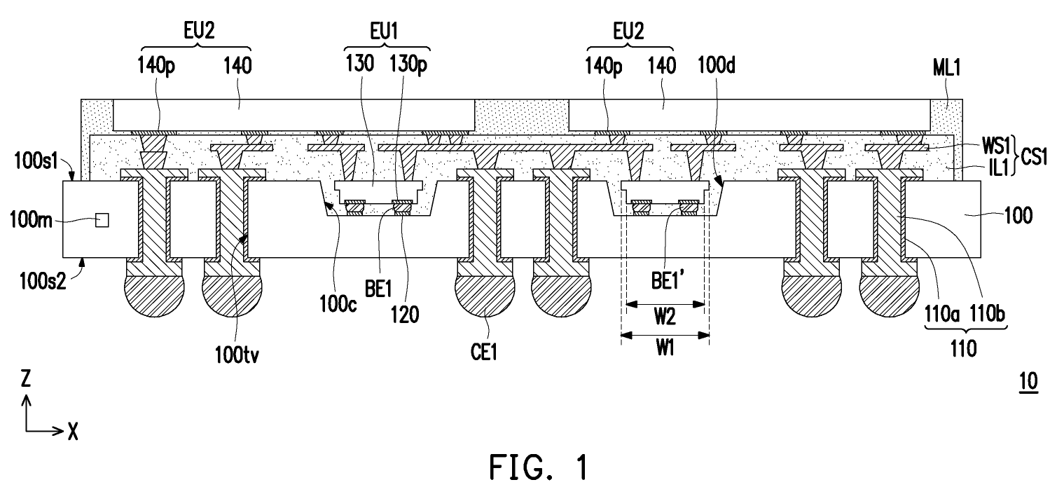

FIG. 1 is a schematic cross-sectional view of an electronic device according to a first embodiment of the present disclosure.

Referring to FIG. 1, The electronic device 10 includes a substrate 100, a first electronic unit EU1, a bonding element BE1, a conductive element 110, and a connection element CE1.

The substrate 100 may include polyimide, glass, silicon, or other suitable substrate materials. In some embodiments, the substrate 100 may be a glass substrate. In some embodiments, the thickness of the substrate 100 in a first direction (e.g., Z direction) may be in a range of 50μm to 1000 μm. The coefficient of thermal expansion (CTE) of the substrate 100 may be in a range of 2 ppm/°C to 10 ppm/°C. This design may serve to buffer the warpage risk that may be caused when subsequent components are formed on the substrate 100.

In the present embodiment, the substrate 100 includes a first surface 100s1 and a second surface 100s2 opposite to each other in the first direction, and includes a cavity 100c extending from the first surface 100s1 thereinto and a through hole 100tv penetrating through the first surface 100s1 and the second surface 100s2. The cavity 100c may be configured between the through holes 100tv. In some embodiments, the substrate 100 may include a mark 100m for alignment or tracing (e.g., an alignment mark or a tracing mark). The through holes 100tv of the substrate 100 may be formed by performing a drilling process, an etching process, or a combination thereof on the substrate 100. The through hole 100tv may have a sidewall, and an extension line of the sidewall forms an included angle θ with the substrate 100 in the Z direction, where 0° ≤ θ ≤ 20°. In some embodiments, the sidewall of the through hole 100tv may have roughness less than that of the first and second surfaces 100s1 and 100s2. Through the above design, the skin effect of the electronic device 10 may be reduced.

The first electronic unit EU1 is disposed in the cavity 100c, and may include a base layer 130 and bonding pads 130p. The electronic unit may be, for example, a known good die (KGD), a diode, an antenna unit, a sensor, a structure formed by semiconductor-related processes, or a component in which a structure formed by semiconductor-related processes is disposed on a base layer (e.g., a base layer including substrate materials such as polyimide, glass, or silicon substrate). The bonding pads 130p may include any suitable conductive material.

In this embodiment, the base layer 130 may include a first side (e.g., front side) on which or in which connection pads for transmitting signals are disposed, and a second side (e.g., back side) opposite to the first side in a first direction (e.g., Z direction), wherein the bonding pads 130p are disposed at the second side of the base layer 130. The connection pads for transmitting signals may be, for example, input/output pads (I/O pads). The bonding pads 130p may be electrically insulated from the I/O pads. In this embodiment, the bonding pads 130p may be embedded in the base layer 130 and include surfaces exposed at the second side of the base layer 130. In some embodiments, the width W1 of the base layer 130 at the first side (e.g., front side) may be greater than the width W2 of the base layer 130 at the second side (e.g., back side) in a second direction (e.g., X direction) perpendicular to the first direction, so that the area where the sidewalls of the base layer 130 are in contact with other film layers may be increased, and thus the reliability of the electronic device 10 may be improved.

The bonding element BE1 is disposed in the cavity 100c and bonds the first electronic unit EU1 to the substrate 100. The bonding element BE1 may include solder having a surface tension capable of supporting the first electronic unit EU1. For example, the bonding element BE1 may include Sn, Cu, Ag, other metal alloys, or combinations thereof. In this embodiment, the bonding element BE1 may be a solder ball, such as a tin ball or other suitable bonding element. The CTE of the bonding element BE1 may be greater than or equal to 10 ppm/°C and less than or equal to 25 ppm/°C. The elastic modulus of the bonding element BE1 may be greater than or equal to 30 GPa and less than or equal to 130 GPa, or greater than or equal to 50 GPa and less than or equal to 110 GPa, or greater than or equal to 70 GPa and less than or equal to 90 GPa. According to some embodiments, a ratio of the CTE of the bonding element BE1 to the CTE of the first electronic unit EU1 may be greater than or equal to 1.5 and less than or equal to 5, so as to improve the bonding quality of the first electronic unit EU1 through such design.

The bonding element BE1' is disposed in the cavity 100d and bonds the first electronic unit EU1 to the substrate 100. The bonding element BE1' is similar as the bonding element BE1.

The conductive elements 110 are disposed in the through holes 100tv. In this embodiment, the conductive element 110 may include a seed layer 110a and a conductive layer 110b disposed on the seed layer 110a. The seed layer 110a may be disposed on the sidewall of the through hole 100tv, and may be further extended onto at least portions of the first and second surfaces 100s1 and 100s2, respectively, in some embodiments. In some embodiments, the seed layer 110a may be formed by chemical vapor deposition (CVD), sputtering, atomic layer deposition (ALD), other suitable deposition methods, or combinations thereof. The seed layer 110a may include any suitable conductive material. In this disclosure, the conductive material may be, for example, Al, Cu, Ti, TiN, W, Ni, Ta, Sn, alloys or combinations thereof. In some embodiments, the seed layer 110a may be directly in contact with the substrate 100. The conductive layer 110b may be formed by electroplating, CVD, sputtering, ALD, resistance heating evaporation, electron beam evaporation, other suitable deposition methods, or combinations thereof. The conductive layer 110b may include a conductive material such as Cu. In some embodiments, the conductive layer 110b may be formed by growing the seed layer 110a through an electroplating process.

The connection elements CE1 are disposed on the conductive elements 110. In this embodiment, the reflow temperature of the bonding element BE1 is higher than the reflow temperature of the connection element CE1. In this way, when a reflow process is performed on the connection element CE1 subsequently, the bonding element BE1 is not easily affected by the reflow process, or the formation of the brittleness materials may be reduced, thereby improving the reliability of the bonding element BE1 bonding the first electronic unit EU1 to the substrate 100. In some embodiments, the connection element CE1 may include a solder ball. The connection element CE1 may include a conductive material having a reflow temperature lower than the reflow temperature of the bonding element BE1, such as tin, nickel, copper, other metal alloys, other suitable materials, or combinations thereof. In some embodiments, the CTE of the connection element CE1 may be greater than or equal to 20 ppm/°C and less than or equal to 30 ppm/°C, and the elastic modulus of the connection element CE1 may be greater than or equal to 20 GPa and less than or equal to 40 GPa. According to some embodiments, the CTE of the bonding element BE1 may be less than the CTE of the connection element CE1, wherein the ratio of the CTE of the connection element CE1 to the CTE of the bonding element BE1 may be greater than or equal to 1.2 and less than or equal to 3. The reliability of the electronic device 10 may be improved through the above design.

In some embodiments, the electronic device 10 may further include a bonding pad 120. In this embodiment, the bonding pad 120 may be disposed on the bottom surface of the cavity 100c, wherein the bonding element BE1 may be disposed between the first electronic unit EU1 and the bonding pad 120, and the bonding element BE1 overlaps with the bonding pad 130p of the first electronic unit EU1 in the first direction (e.g., Z direction). In this embodiment, based on the factors of surface energy and wettability, the bonding element BE1 tends to adhere to the surfaces with good wettability and/or the surfaces with high surface energy when performing a reflow process. For example, the metal surfaces such as copper, nickel, or gold have good wettability and high surface energy as compared to the insulation surfaces of the polymer materials. Therefore, when the first electronic unit EU1 is placed on the bonding element BE1 and then a reflow process is performed, the bonding pad 130p of the first electronic unit EU1 may be aligned with the bonding pad 120 disposed on the bottom surface of the cavity 100c through the bonding element BE1 based on the above factors. In other words, the first electronic unit EU1 may have a self-align effect through the arrangement of the bonding element BE1 and the bonding pad 120, which is beneficial for improving the reliability of the electronic device 10.

In some embodiments, the electronic device 10 may further include a circuit structure CS1. In this embodiment, the circuit structure CS1 may be disposed on the first surface 100s1 of the substrate 100. The circuit structure CS1 may include an insulation layer IL1 formed on the substrate 100 and a wiring structure WS1 formed in the insulation layer IL1, wherein the wiring structure WS1 may be electrically connected to the first electronic unit EU1 and the conductive element 110. The circuit structure CS1 may include at least one insulation layer and at least one conductive layer, so as to redistribute the wiring line and/or to further enhance the fan-out area of the wiring line, or different electronic units may be electrically connected to each other through the circuit structure CS1.

The insulation layer IL1 may include insulation layers alternately stacked along the Z direction. In this embodiment, the insulation layer IL1 may include a filling insulation layer filled in the cavity 100c and surrounding the first electronic unit EU1. In some embodiments, the material of the filling insulation layer surrounding the first electronic unit EU1 in the insulation layer IL1 may be different from the material of the insulation layer surrounding the wiring structure WS1 in the insulation layer IL1, but is not limited thereto. The wiring structure WS1 may include conductive patterns stacked along the Z direction and conductive vias connecting the conductive patterns. The insulation layer IL1 may include organic materials or inorganic materials. The wiring structure WS1 may include any suitable conductive material.

In some embodiments, the electronic device 10 may further include second electronic units EU2 provided on the circuit structure CS1 and electrically connected to the first electronic units EU1 and the conductive elements 110 through the circuit structure CS1. The second electronic unit EU2 may include a second electronic component 140 and connection pads 140p. The second electronic component 140 may include a die, a chip, a diode, an antenna unit, a memory unit, a photonic integrated circuit (PIC) unit, a sensor, or structures of semiconductor-related processes. The connection pads 140p may be located at one side of the second electronic component 140. In the embodiment where the electronic component is a chip, the side at which the connection pads 140p is disposed may be referred to as the front side or active side. In this embodiment, the second electronic unit EU2 may be different from the first electronic unit EU1. The connection pads 140p may include any suitable conductive material.

In some embodiments, the electronic device 10 may further include a packaging layer ML1. The packaging layer ML1 may prevent the first electronic units EU1 and/or the second electronic units EU2 from being affected by external moisture, thereby improving the reliability of the electronic device 10. The packaging layer ML1 may include any suitable packaging material, such as epoxy molding compound (EMC).

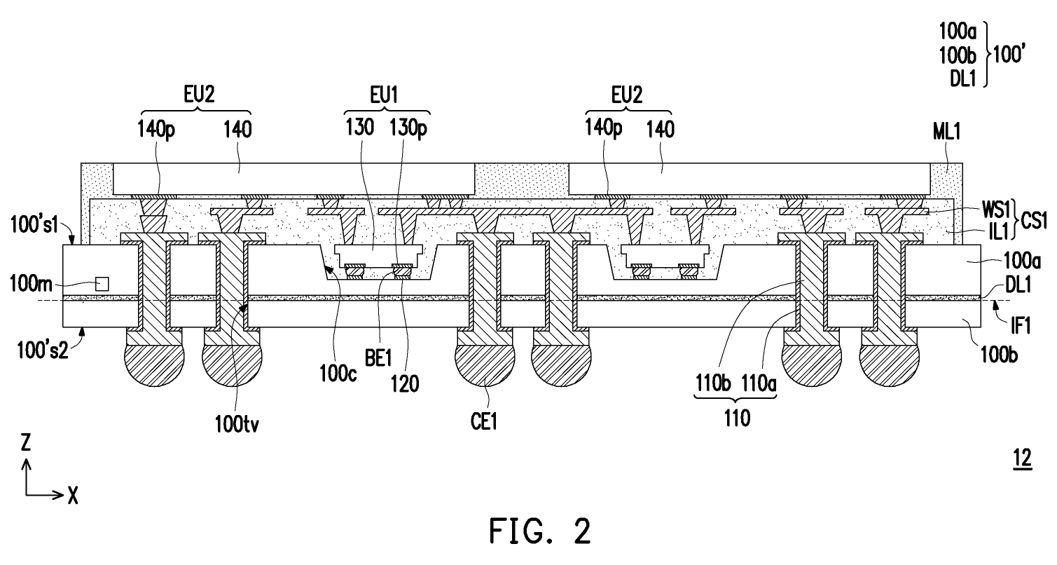

FIG. 2 is a cross-sectional schematic diagram of an electronic device according to a second embodiment of the present disclosure. The electronic device 12 shown in FIG. 2 is similar to the electronic device 10 shown in FIG. 1, with the main difference being that the substrate 100' of the electronic device 12 is different from the substrate 100 of the electronic device 10. Other identical or similar elements are represented by the same or similar reference numerals or symbols and will not be repeatedly described herein.

Referring to FIG. 2, the substrate 100' of the electronic device 12 may include a first substrate 100a, a second substrate 100b, and a dielectric layer DL1 therebetween. The substrate 100' may include a first surface 100's1 and a second surface 100's2 opposite to each other in the Z direction, wherein a top surface of the first substrate 100a may be corresponded to the first surface 100's1 of the substrate 100', and a bottom surface of the second substrate 100b may be corresponded to the second surface 100's2 of the substrate 100'. The first and second substrates 100a and 100b may be made of the same or different materials. The first and second substrates 100a and 100b may have the same or different CTEs. For example, the CTE of the first substrate 100a may be smaller than that of the second substrate 100b. The first and second substrates 100a and 100b may have the same or different rigidities. For example, the rigidity of the first substrate 100a may be smaller than that of the second substrate 100b. In this embodiment, the first and second substrates 100a and 100b may have the same or different warpage tendencies. For example, the warpage tendency of the first substrate 100a is opposite to that of the second substrate 100b. The warpage tendency is that the outer side of the substrate warps upwardly or downwardly in the first direction. The dielectric layer DL1 may include any suitable organic materials or inorganic materials as described above, such as silicon, silicon oxide, silicon-based material, or silicon-based mixture. In this embodiment, the dielectric layer DL1 may be disposed on the bottom surface of the first substrate 100a and bonded to the second substrate 100b through a manner of hybrid bonding. For example, at the bonding interface IF1, first portions of the conductive layers 110b in the first substrate 100a and second portions of the conductive layers 110b in the second substrate 100b are bonded to each other by metal to metal bonding, and portions where the dielectric layer DL1 and the second substrate 100b in contact with each other are bonded to each other by oxide to oxide bonding. In this embodiment, a thickness of the first substrate 100a may be greater than that of the second substrate 100b in the Z direction.

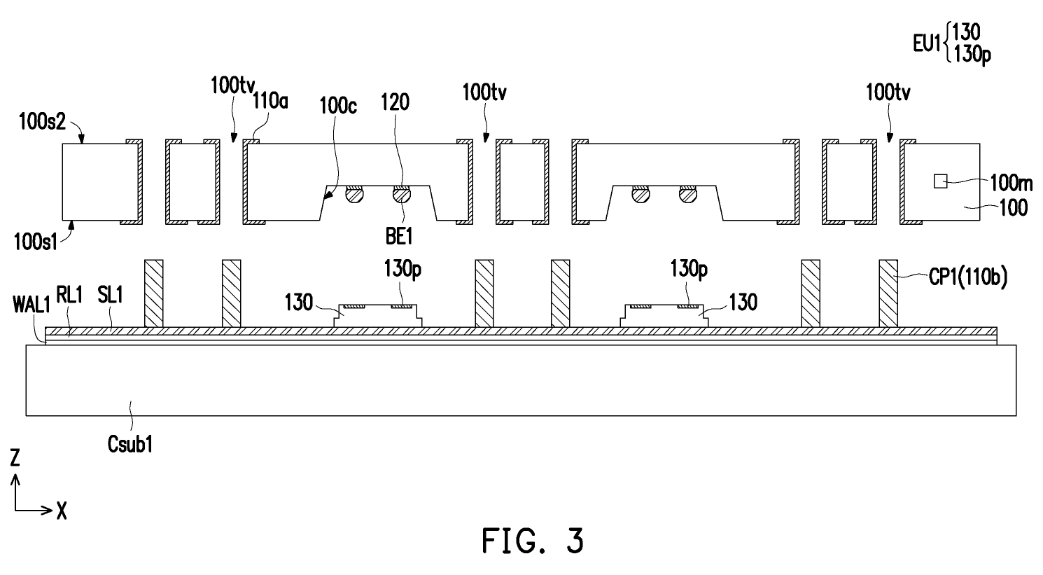

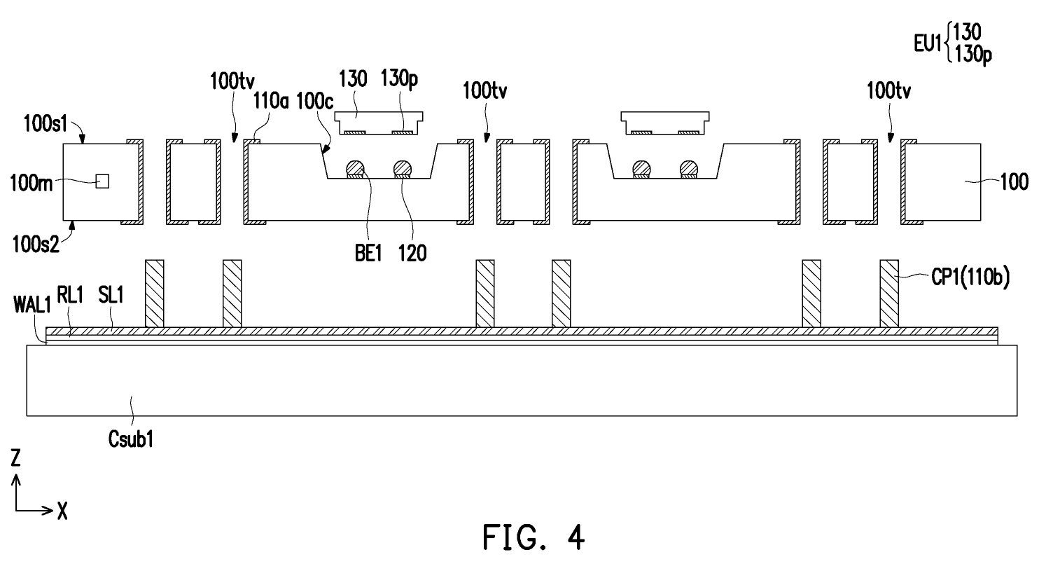

FIG. 3 is a schematic cross-sectional view of a method for manufacturing an electronic device according to an embodiment of the present disclosure. FIG. 4 is a schematic cross-sectional view of a method manufacturing for an electronic device according to another embodiment of the present disclosure. FIG. 3 and FIG. 4 show some steps of methods for manufacturing electronic devices in different embodiments of the present disclosure.

Referring to FIGS. 1 and 3 , the conductive elements 110 may be provided in the through holes 100tv through the steps shown below. First, a carrier Csub1 is provided. The material of the carrier Csub1 may include glass, quartz, sapphire, ceramic, stainless steel, silicon wafer, other suitable substrate materials, or combinations thereof. Next, an anti-warpage layer WAL1, a release layer RL1, and a seed layer SL1 are sequentially provided on the carrier Csub1.

The anti-warpage layer WAL1 may be a single-layer or multi-layer structure including suitable organic materials and/or inorganic materials (e.g., SiO₂, SixNy, or SiOxNy). The release layer RL1 may be a temporary bonding layer, which may include thermal-type or optical-type release materials with adhesive, so that the working units, components, or film layers subsequently formed thereon may be temporarily bonded to the release layer RL1. In other words, the release layer RL1 may assist in removing working units, components, or film layers from the carrier Csub1. The seed layer SL1 may include any suitable conductive material.

Then, referring to FIG. 3, the conductive pillars CP1 are formed above the carrier Csub1 at positions corresponding to the through holes 100tv of the substrate 100. Subsequently, the substrate 100 is bonded to the carrier Csub1 in a manner that the through holes 100tv are aligned with the conductive pillars CP1. Thereafter, an electroplating process is performed on the seed layer 110a formed on the surface of the through holes 100tv to form the conductive elements 110 as shown in FIG. 1 in the through holes 100tv. Since the conductive pillars CP1 are first formed on the carrier Csub1 before the first electronic units EU1 are bonded to the substrate 100, the impact of the process for forming the conductive pillars CP1 on the first electronic units EU1 may be reduced, thereby improving the reliability of the electronic device 10. In this embodiment, the bonding pads 120 are provided on the bottom surface of the cavity 100c before the bonding elements BE1 are provided in the cavity 100c.

In this embodiment, when the first electronic units EU1 are provided on the carrier Csub1 at positions corresponding to the cavities 100c of the substrate 100, the first surface 100s1 of the substrate 100 is bonded to the carrier Csub1 in a manner that the through holes 100tv and the cavities 100c are aligned with the conductive pillars CP1 and the first electronic units EU1, respectively. Alternatively, as shown in FIG. 4, when the first electronic units EU1 have been provided in the cavities 100c of the substrate 100, the second surface 100s2 of the substrate 100 is bonded to the carrier Csub1.

In some other embodiments, as shown in FIG. 2 and FIG. 3, after bonding the first surface 100s1 of the substrate 100 to the carrier Csub1, another substrate having a thickness smaller than the thickness of the substrate 100 may be provided on the second surface 100s2 of the substrate 100 to form a substrate similar to the substrate 100' shown in FIG. 2. In this embodiment, other conductive pillars (corresponding to the second portions of the conductive layers 110b in the second substrate 100b) may be formed in another substrate corresponding to the conductive pillars CP1 (corresponding to the first portions of the conductive layers 110b in the first substrate 100a). In some embodiments, another substrate may be bonded to the second surface 100s2 of the substrate 100 by a manner of hybrid bonding.

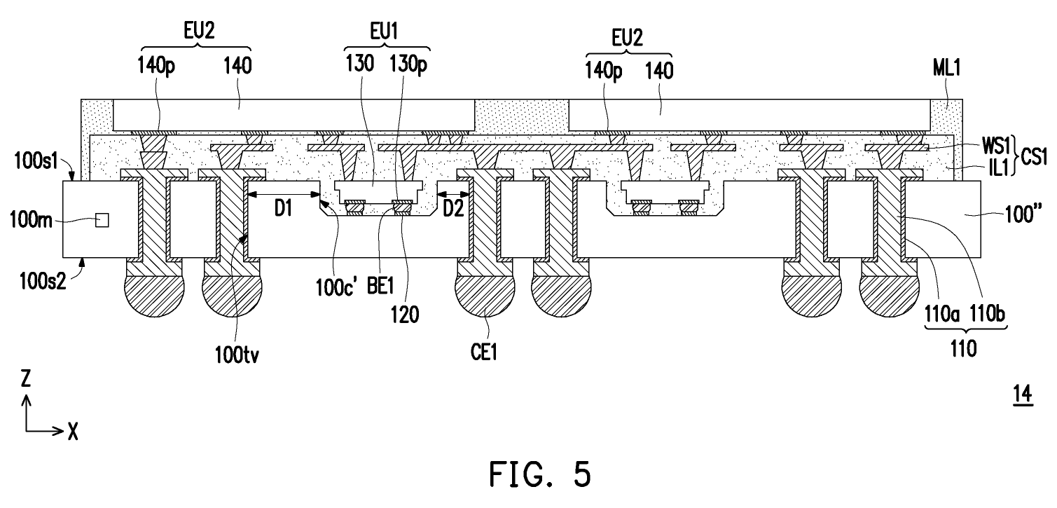

FIG. 5 is a schematic cross-sectional view of an electronic device according to a third embodiment of the present disclosure. The electronic device 14 shown in FIG. 5 is similar to the electronic device 10 shown in FIG. 1, and the main difference is that the cavity 100c' of the electronic device 14 is different from the cavity 100c of the electronic device 10. Other same or similar elements are represented by the same or similar reference numerals or symbols, and will not be repeatedly described herein.

Referring to FIG. 5, the corner where the bottom surface of the cavity 100c' connects with the sidewall may have a chamfering design and the extending direction of the sidewall may be parallel to the Z direction. In this embodiment, the two opposite sidewalls of the cavity 100c' in the X direction are respectively spaced apart from the adjacent through holes 100tv by a first distance D1 and a second distance D2, wherein the ratio of the second distance D2 to the first distance D1 (i.e., D2/D1) is in a range of 0.6 to 1.5, which is beneficial for reducing the risk of cracks in the substrate 100'' during the process of forming the through holes 100tv.

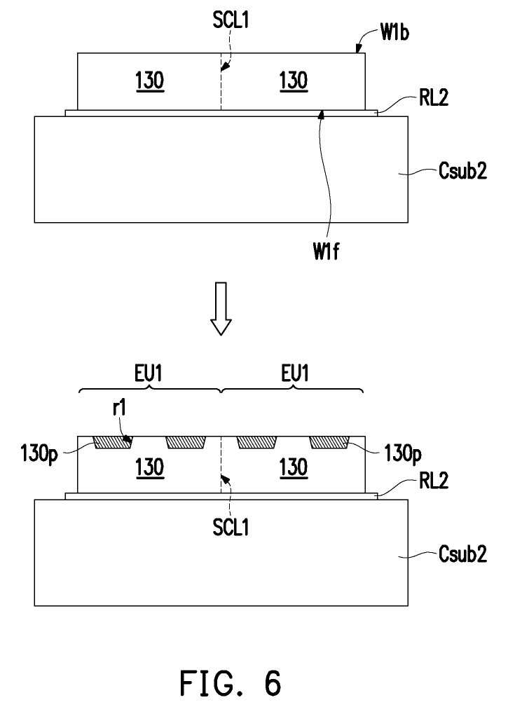

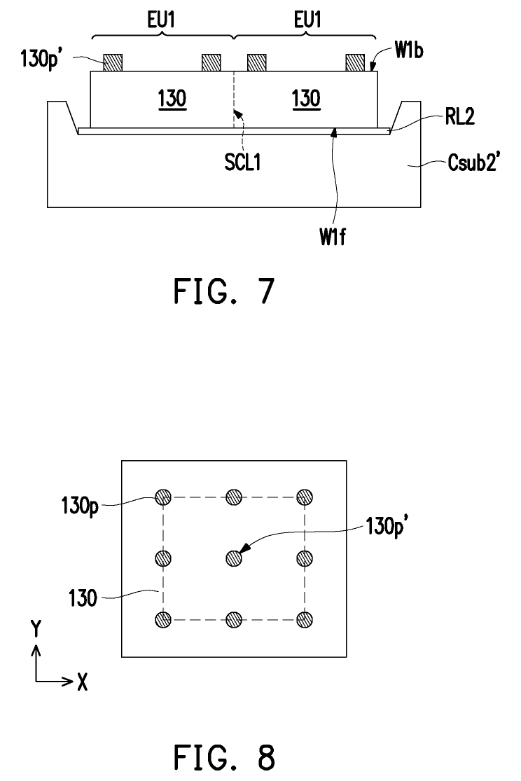

FIG. 6 and FIG. 7 are schematic cross-sectional views of methods for manufacturing a first electronic unit according to different embodiments of the present disclosure.FIG. 8 is a schematic top view of a first electronic unit of the present disclosure.

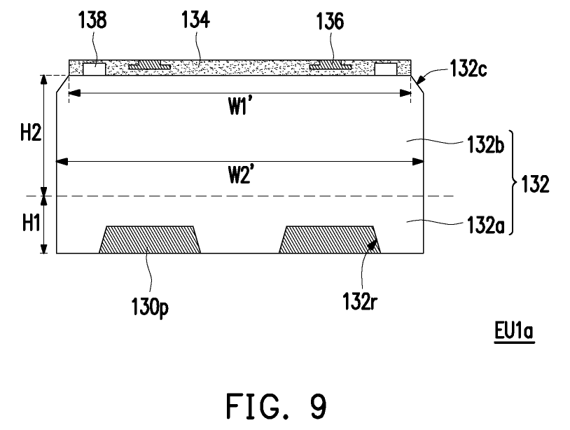

Referring to FIG. 6, the first electronic unit EU1 shown in FIG. 1 may be formed through the following steps. First, a carrier Csub2 is provided. Next, a release layer RL2 is provided on the carrier Csub2. The carrier Csub2 may include materials as listed for the carrier Csub1 above. The release layer RL2 may include materials as listed for the release layer RL1 above. Then, a wafer including base layers 130 is provided on the release layer RL2. In some embodiments, the carrier Csub2 may have a space for accommodating the wafer to improve the stability of the processes performing on the wafer (e.g., the carrier Csub2' shown in FIG. 7). In this embodiment, the wafer is provided on the release layer RL2 with the front side W1f facing the release layer RL2. Thereafter, the conductive materials are filled into cavities r1, formed by performing processes such as laser, sawing, or etching on the back side W1b of the wafer, to form the bonding pads 130p. In this embodiment, the top surface of the bonding pads 130p and the back side W1b of the wafer may be coplanar. Alternatively, the top surface of the bonding pads 130p may be higher than the back side W1b of the wafer (e.g., the bonding pads 130p' shown in FIG. 7). In some embodiments, the bonding pads 130p' may be formed on the back side W1b of the wafer through the following steps. First, a seed layer is provided on the back side W1b of the wafer. Next, the seed layer is grown to form a conductive layer through an electroplating process. Then, a patterning process is performed on the conductive layer and the seed layer to form the bonding pads 130p' shown in FIG. 7. Then, a singulation process may be performed along the scribe line SCL1 after the bonding pads 130p are formed to form individual first electronic units EU1. In some embodiments, the shape of the base layer 130 shown in FIG. 1 may be formed through the above singulation process. In some other embodiments, the shape of the base layer 132 shown in FIG. 9 may be formed through the above singulation process to include sidewalls with trapezoidal profiles.

In this embodiment, the bonding pads 130p may be configured to be plural in each base layer 130, and the bonding pads 130p, as shown in FIG. 8, are formed to be mirror-symmetric in the horizontal direction, so as to improve the reliability of the electronic device 10. In some embodiments, as shown in FIG. 8, a geometric center (e.g., dashed line) of the bonding pads 130p should be close to the geometric center of the first electronic unit EU1 and/or the geometric center of the bonding pads 130p should be close to the geometric center of another bonding pad 130p' surrounded by the plurality of bonding pads 130p. In detail, the geometric center of the bonding pads 130p may be the center of a geometric pattern (e.g., dashed line) formed by the lines connecting the centers of the adjacent bonding pads 130p in the X direction or Y direction. That is, the distance between the geometric center of the bonding pads 130p and the geometric center of the first electronic unit EU1 should be less than or equal to 10 µm and the distance between the geometric center of the bonding pads 130p and the geometric center of another bonding pad 130p' should be less than or equal to 10µm, thereby improving bonding quality.

FIG. 9 is a schematic cross-sectional view of a first electronic unit according to different embodiments of the present disclosure.

Referring to FIG. 9, the first electronic unit EU1a may include a base layer 132, bonding pads 130p, an insulation layer 134, connection pads 136, and a wall body 138. The width W1' of the base layer 132 at the first side (e.g., front side) may be smaller than the width W2' of the base layer 132 at the second side (e.g., back side) in the X direction. The base layer 132 of the first electronic unit EU1b may include a first portion 132a and a second portion 132b having a chamfer 132c at a side edge adjacent to the active layer on the first portion 132a. In some embodiments, the base layer 132 may include a first side on which an active layer is disposed and a second side opposite to the first side and in which or on which the bonding pads 130p are disposed. In this embodiment, the bonding pads 130p may be embedded in recesses 132r of the base layer 132, and the active layer may include an insulation layer 134 disposed on the base layer 132 and the connection pads 136 and the wall body 138 formed in the insulation layer 134. In this embodiment, the surface roughness of the sidewall of the first portion 132a may be smaller than the surface roughness of the sidewall of the second portion 132b. In this embodiment, the ratio of the height H2 of the second portion 132b to the height H1 of the first portion 132a (i.e., H2/H1) is in a range of 0.8 to 3, which is beneficial for improving the adhesion between the base layer 132' and other film layers.

The insulation layer 134 may include any suitable insulation material. The connection pads 136 may be electrically connected to the wiring structure WS1 of the circuit structure CS1 as shown in FIG. 1. The connection pads 136 may include any suitable conductive material. In some embodiments, the wall body 138 may be disposed at edges adjacent to the base layer 132 (at edges adjacent to the scribe line SCL1 shown in FIG. 6 or FIG. 7), which is beneficial for reducing the risk of delamination of the active layer during the singulation process. The wall body 138 may include any suitable material.

Hereinafter, a method for manufacturing the electronic device 10 of the present disclosure will be exemplified with reference to FIG. 1, but the method for manufacturing the electronic device 10 shown in FIG. 1 is not limited thereto.

Referring to FIG. 1, first, a substrate 100 is provided. The substrate 100 includes a first surface 100s1 and a second surface 100s2 opposite to each other in a first direction (e.g., Z direction), and includes a cavity 100c extending from the first surface 100s1 into the substrate 100 and a through hole 100tv penetrating through the first surface 100s1 and the second surface 100s2. Next, a bonding element BE1 is provided in the cavity 100c. Then, a first electronic unit EU1 is provided on the bonding element BE1, such that the first electronic unit EU1 is bonded to the substrate 100 through the bonding element BE1. Subsequently, a conductive element 110 is provided in the through hole 100tv. Thereafter, a connection element CE1 is provided on the conductive element 110, wherein the reflow temperature of the bonding element BE1 is higher than the reflow temperature of the connection element CE1.

In summary, in the electronic device and the method for manufacturing the same according to the embodiments of the present disclosure, the reflow temperature of the bonding element is designed to be higher than the reflow temperature of the connection element, so that when a reflow process is subsequently performed on the connection element, the bonding element is not easily affected by the reflow process, thereby improving the reliability of the bonding element bonding the first electronic unit to the substrate.

What is claimed is:

1. An electronic device, comprising:
a substrate comprising a first surface and a second surface opposite to each other in a first direction, wherein the substrate comprises a cavity and a through hole penetrating through the first surface and the second surface;
a bonding element disposed in the cavity;
a first electronic unit disposed in the cavity and bonded to the substrate through the bonding element;
a conductive element disposed in the through hole and electrically connected to the first electronic unit;
a circuit structure disposed on the first surface of the substrate and electrically connected to the first electronic unit and the conductive element; and
a connection element disposed on the conductive element, wherein a reflow temperature of the bonding element is higher than a reflow temperature of the connection element.

2. The electronic device according to claim 1, further comprising:
a first bonding pad disposed on a bottom surface of the cavity or embedded in the substrate below the bottom surface of the cavity, wherein the bonding element is disposed between the first electronic unit and the first bonding pad, and the bonding element overlaps with a second bonding pad of the first electronic unit in the first direction.

3. The electronic device according to claim 2, wherein the first electronic unit comprises a base layer and a connection pad, wherein the connection pad is disposed at a first side of the base layer, and the second bonding pad is disposed at a second side opposite to the first side of the base layer in the first direction.

4. The electronic device according to claim 3, wherein the second bonding pad is embedded in a recess of the base layer.

5. The electronic device according to claim 3, wherein in a second direction perpendicular to the first direction, a width of the base layer at the first side is greater than a width of the base layer at the second side.

6. The electronic device according to claim 2, wherein the second bonding pad is configured to be plural, and a plurality of second bonding pads are configured to be mirror-symmetric in a second direction perpendicular to the first direction.

7. The electronic device according to claim 6, wherein a distance between a geometric center of the plurality of second bonding pads and a geometric center of the first electronic unit is less than 10 µm.

8. A method for manufacturing an electronic device, comprising:
providing a substrate, wherein the substrate comprises a first surface and a second surface opposite to each other in a first direction, and comprises a cavity extending from the first surface into the substrate and a through hole penetrating through the first surface and the second surface;
providing a bonding element in the cavity;
providing a first electronic unit on the bonding element, such that the first electronic unit is bonded to the substrate through the bonding element;
providing a conductive element electrically connected to the first electronic unit in the through hole; and
providing a connection element on the conductive element, wherein a reflow temperature of the bonding element is higher than a reflow temperature of the connection element.

9. The method according to claim 8, wherein steps of providing the conductive element in the through hole comprises:
providing a carrier;
forming a conductive pillar on the carrier at a position corresponding to the through hole of the substrate;
bonding the substrate to the carrier in a manner that the through hole is aligned with the conductive pillar; and
performing an electroplating process on a seed layer formed on a surface of the through hole to form the conductive element in the through hole.

10. The method according to claim 9, wherein when the first electronic unit is provided on the carrier at a position corresponding to the cavity of the substrate, the first surface of the substrate is bonded to the carrier.

11. The method according to claim 10, further comprising:
providing another substrate on the second surface of the substrate, wherein a thickness of the another substrate in the first direction is less than a thickness of the substrate in the first direction.

12. The method according to claim 11, wherein the another substrate is formed with another conductive element corresponding to the conductive element, and the another substrate is bonded to the second surface of the substrate by a manner of hybrid bonding.

13. The method according to claim 9, wherein as the first electronic unit has been provided in the cavity of the substrate, the second surface of the substrate is bonded to the carrier.

14. The method according to claim 8, further comprising:
before providing the bonding element in the cavity, providing a first bonding pad on a bottom surface of the cavity or embedding the first bonding pad in the substrate below the bottom surface of the cavity,
wherein the bonding element is formed between the first electronic unit and the first bonding pad, and the bonding element overlaps with a second bonding pad of the first electronic unit in the first direction.

15. The method according to claim 14, further comprising:
providing a circuit structure on the first surface of the substrate, wherein the circuit structure comprises a wiring structure electrically connected to the first electronic unit and the conductive element.

16. The method according to claim 15, wherein the first electronic unit comprises a base layer and a connection pad, wherein the connection pad is formed at a first side of the base layer, and the second bonding pad is formed at a second side opposite to the first side of the base layer in the first direction.

17. The method according to claim 16, wherein the second bonding pad is embedded in a recess of the base layer.

18. The method according to claim 16, wherein a width of the base layer at the first side is greater than a width of the base layer at the second side in a second direction perpendicular to the first direction.

19. The method according to claim 15, further comprising:
providing a second electronic unit on the circuit structure, wherein the second electronic unit is electrically connected to the first electronic unit and the conductive element through the wiring structure.

20. The method according to claim 14, wherein the second bonding pad is configured to be plural, and a plurality of second bonding pads are formed to be mirror-symmetric in a second direction perpendicular to the first direction.
